(19) United States
(12) Patent Application Publication
(10) Pub. No.: US 2014/0098496 A1
(43) Pub. Date: Apr. 10, 2014

(54) POWER CONVERSION APPARATUS INCLUDING SEMICONDUCTOR MODULES AND COOLER

(71) Applicant: DENSO CORPORATION, Kariya-city (JP)

(72) Inventor: Akira NAKASAKA, Kariya-shi (JP)

(73) Assignee: DENSO CORPORATION, Kariya-city (JP)

(21) Appl. No.: 14/050,787

(22) Filed: Oct. 10, 2013

(30) Foreign Application Priority Data
Oct. 10, 2012 (JP) 2012-225375

(51) Int. Cl. H05K 7/20

(52) U.S. Cl. CPC H05K 7/20927
USPC 361/699

(57) ABSTRACT

The power conversion apparatus includes semiconductor modules constituting a part of a power conversion circuit, a cooler including coolant passages, and a frame holding the semiconductor modules and the cooler. The semiconductor modules and the coolant passages are stacked on one another to form a stacked body. The cooler includes a pair of inlet/outlet tubes for introducing and discharging a coolant, the pair of the coolant inlet/outlet tubes extending from one of the coolant passages which is located at one end in a stacking direction of the stacked body to outside of the frame. Each of the pair of the coolant inlet/outlet tubes includes a proximal end portion located inside the frame and a distal end portion located outside the frame. In at least one of the pair of the inlet/outlet tubes, the proximal end portion has an outer diameter smaller than an outer diameter of the distal end portion.

This application claims priority to Japanese Patent Application No. 2012-225375 filed on Oct. 10, 2012, the entire contents of which are hereby incorporated by reference.

### BACKGROUND OF THE INVENTION

1. Field of the Invention

The present invention relates to a power conversion apparatus including semiconductor modules and a cooler.

2. Description of Related Art

An electric vehicle and a hybrid vehicle are provided with a power conversion apparatus such as an inverter, which includes semiconductor modules constituting a power conversion circuit and a cooler for cooling the semiconductor modules. Meanwhile, there is demand to provide a high-output and compact power conversion apparatus including semiconductor modules constituting a power conversion circuit and a cooler for cooling the semiconductor modules.

Japanese Patent Application Laid-open No. 2011-182628 describes such a power conversion apparatus having a structure in which the semiconductor modules and coolant passages are stacked on one another so that each semiconductor module can be cooled at both main surfaces. The power conversion apparatus described in this patent document is designed to be able to output high power by efficiently removing heat generated from the semiconductor modules.

Conventional power conversion apparatuses including the one described in the above patent document use a coolant circulation pump, and accordingly it is necessary to minimize the load of the pump as much as possible. Hence, it is common that the inner diameter of external tubes for connecting the power conversion apparatus and the pump is made large as much as possible to reduce the flow resistance of the coolant as much as possible. Since the size of the inlet/outlet tube of the cooler has to conform to the size of the external tube, there is a limitation in reducing the size of the cooler.

### SUMMARY

An exemplary embodiment provides a power conversion apparatus including:
semiconductor modules constituting a part of a power conversion circuit;
a cooler including coolant passages; and
a frame holding the semiconductor modules and the cooler;
wherein
the semiconductor modules and the coolant passages are stacked on one another so as to form a stacked body,
the cooler includes a pair of inlet/outlet tubes for introducing and discharging a coolant, the pair of the coolant inlet/outlet tubes extending from one of the coolant passages which is located at one end in a stacking direction of the stacked body to outside of the frame,
each of the pair of the coolant inlet/outlet tubes includes a proximal end portion located inside the frame and a distal end portion located outside the frame, and
in at least one of the pair of the inlet/outlet tubes, the proximal end portion has an outer diameter smaller than an outer diameter of the distal end portion.

According to the exemplary embodiment, there is provided a high-output and compact power conversion apparatus including semiconductor modules and a cooler.

Other advantages and features of the invention will become apparent from the following description including the drawings and claims.

### BRIEF DESCRIPTION OF THE DRAWINGS

In the accompanying drawings:

FIG. 1 is a plan view of a power conversion apparatus according to a first embodiment of the invention as viewed along the height direction before its control circuit is assembled;

FIG. 2 is a plan view of the power conversion apparatus as viewed along the height direction after its control circuit is assembled;

FIG. 3 is a diagram showing the power conversion apparatus as viewed along the width direction;

FIG. 4 is a plan view of a power conversion apparatus according to a second embodiment of the invention; and

FIG. 5 is a plan view of a power conversion apparatus according to a third embodiment of the invention.

### PREFERRED EMBODIMENTS OF THE INVENTION

In the below described embodiments, the same reference numerals or characters are used to denote the same or equivalent parts or components.

### First Embodiment

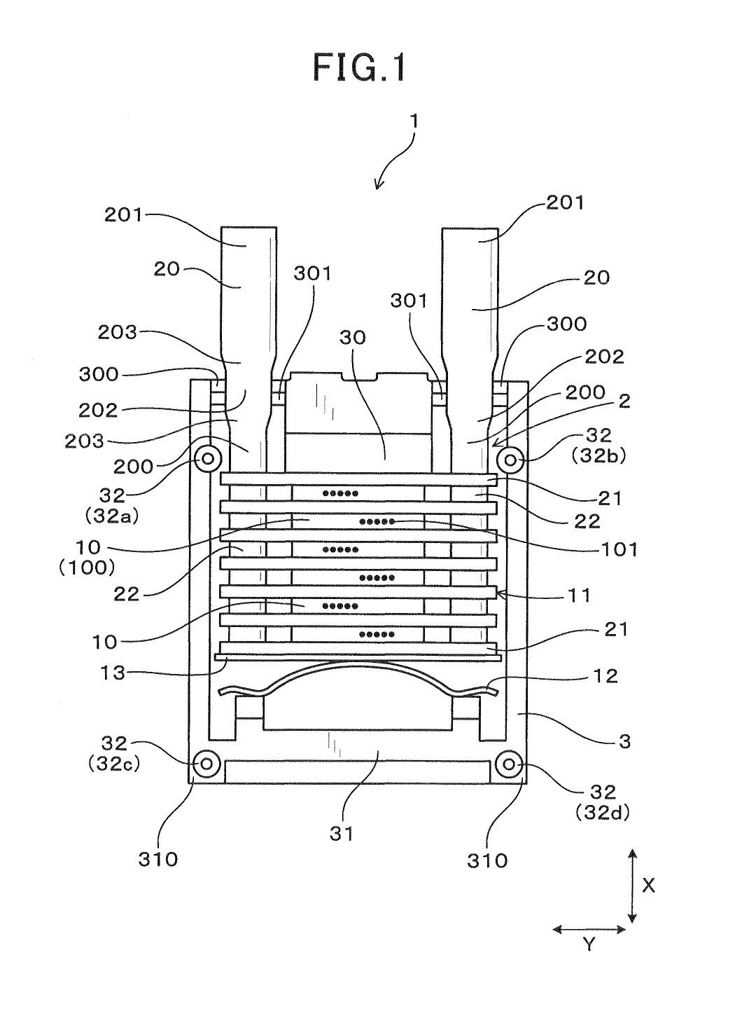

A power conversion apparatus 1 according 1 to a first embodiment of the invention is described with reference to FIGS. 1 to 3. As shown in FIG. 1, the power conversion apparatus 1 includes a plurality of semiconductor modules 10 which constitute a part of a power conversion circuit, a cooler 2 having a plurality of cooling tubes 21 which form coolant passages for cooling the semiconductor modules 10, and a frame 3 holding the semiconductor modules 10 and the cooler 2. The semiconductor modules 10 and the cooling tubes 21 are stacked on one another so as to form a stacked body 11.

The cooler 2 includes a pair of coolant inlet/outlet tubes for introducing and discharging a coolant. The coolant inlet/outlet tubes 20 are disposed so as to extend from one of the cooling tubes 21 which is located at one end of the stacked body 11 in the stacking direction to the outside of the frame 3. Each of the coolant inlet/outlet tubes 20 is formed such that the outer diameter of its proximal end portion 200 disposed inside the frame 3 is smaller than its distal end portion 201 disposed outside the frame 3.

In the following descriptions, the stacking direction of the stacked body 11 is referred to as the “stacking direction X”, and the flow direction of the coolant perpendicular to the stacking direction X is referred to as the “width direction Y”. Further, the direction perpendicular to both the stacking direction X and the width direction Y is referred to as the “height direction Z”.

As shown in FIG. 1, the semiconductor modules 10 and the cooler 2 are held by the frame 3 surrounding them in all four directions. The frame 3 includes a first wall portion 30 located at one end thereof in the stacking direction X. The first wall portion 30 is formed with a pair of notch openings 300. The pair of the coolant inlet/outlet tubes 20 project from the pair of the notch openings 300 toward the outside of the frame 3. Each of the notch openings 300 includes a supporting portion 3-1 for supporting an intermediate portion 202 (to be explained later) of the coolant inlet/outlet tube 20 in the height direction Z, so that the intermediate portion 202 is sandwiched between a not-shown clamp and the supporting portion 301.

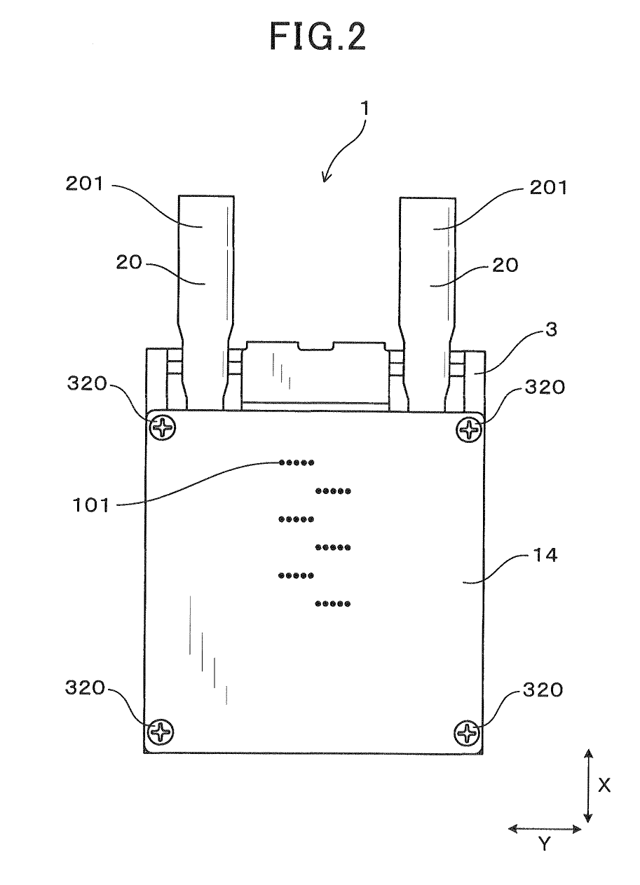

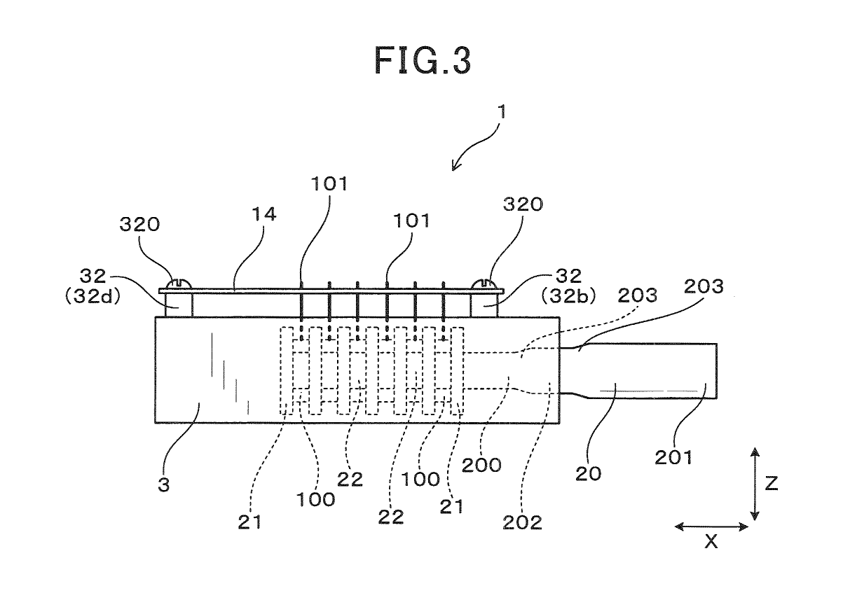

As shown in FIG. 1, the frame 3 includes four bosses 32a, 32b, 32c, 32d (collectively referred to as bosses 32) formed so as to project in the height direction Z perpendicular to both the stacking direction X and the width direction Y. As shown in FIGS. 2 and 3, these bosses 32 are formed such that a control circuit board 14 for controlling the operations of the semiconductor modules 10 can be fastened by bolts 320. As shown in FIG. 1, the bosses 32a and 32b are disposed adjacently outside in the width direction Y of the proximal end portions 200 of the pair of the coolant inlet/outlet tubes 20, respectively. The other two bosses 32c and 32d are disposed at the two corners 310 of a second wall portion 31 located at the other end of the frame 3 in the stacking direction X, respectively.

As shown in FIGS. 1 and 3, each of the pair of the coolant inlet/outlet tubes 20 is formed so as to extend from the cooling pipe 21 located on the side of the first wall portion 30 to the outside of the frame 3. The diameter of each coolant inlet/outlet tube 20, which extends in the stacking direction X from the proximal end portion 200 is increased in two steps so that the distal end portion 210 is formed at its tip end. That is, the intermediate portion 202 having a diameter between those of the proximal end portion 200 and the distal end portion 201 is formed between them, and a taper-shaped step portion 203 is formed in the boundary between the proximal end portion 200 and intermediate portion 202 and in the boundary between the intermediate portion 202 and the distal end portion 201.

As shown in FIG. 1, the cooler 2 has the structure in which the cooling tubes 21 through which the coolant flows are arranged at a certain spacing in the stacking direction X, and each adjacent two of the cooling tubes 21 are joined to each other through a joint tube 22 at their both ends. The proximal end portions 200 of the pair of the coolant inlet/outlet tubes 20 are connected to the longitudinal ends of the cooling tubes 21 located at the one end of the frame 3 in the stacking direction X. In this embodiment, the outer diameter of the joint tube 22 is approximately the same as the proximal end portion 200.

Each semiconductor module 10 include a roughly rectangular main body section 100, control terminals 101 for controlling operation of the main body section 100, and main terminals (not shown) for receiving and outputting electric power in and from the main body section 100. The control terminals 101 and the main terminals project in the opposite directions from the main body section 100. In this embodiment, the control terminals 101 project in the height direction Z to be electrically connected to the control circuit board 14. The main body section 100 incorporates an IGBT (Insulated Gate Bipolar Transistor) or a MOSFET (Metal-Oxide-Semiconductor Field Effect Transistor) as a switching element.

As shown in FIG. 1, the semiconductor modules 10 are arranged in the stacking direction such that each one of them is disposed between each adjacent two of the cooling tubes 21. Each semiconductor module 10 is sandwiched between each adjacent two of the cooling tubes 21 at both its main surfaces. That is, the cooling tubes 21 and the semiconductor modules 10 are stacked on one another to form the stacked body 11. Each two of the semiconductor modules 10 adjacent to each other in the stacking direction X are disposed such that the control terminals 101 of one of them are displaced from the control terminals in the width direction Y.

The cooler 2 having the above described structure operates such that the coolant introduced from one of the coolant inlet/outlet tubes 20 passes through the joint tubes 22 to flow in the longitudinal direction of the cooler 2 while being distributed to the respective cooling pipes 21. The coolant exchanges heat with the semiconductor modules 10 while flowing through the cooling tubes 21. The coolant whose temperature has risen due to the heat exchange passes through the joint tubes 22 on the downstream side to reach the other coolant inlet/outlet tube 20, and is discharged from the cooler 2.

As shown in FIG. 1, the stacked body 11 constituted of the cooling tubes 21 and the semiconductor modules 10 is pressed in the stacking direction X from the side opposite to the coolant inlet/outlet tubes 20 by a spring member 12. More specifically, the cooling tubes 21 located at the one end of the frame 3 are in contact with the first wall portion 30 formed with the notch openings 300, and the spring member 12 biased to expand in the stacking direction X is disposed between the second wall portion 31 and the cooling tubes 21 located at the other end of the frame 3. An abutment plate 13 is disposed between the spring member 12 and the cooling tubes 21 to prevent deformation of the cooling tubes 21.

The first embodiment provides the following advantages. The power conversion apparatus 1 has the structure in which the outer diameter of the proximal end portion 200 of at least one of the pair of the coolant inlet/outlet tubes 20 is smaller than that of the distal end portion 201. This makes it possible to reduce the volume of possession of the coolant inlet/outlet tubes 20 within the frame 3, to thereby reduce the dimension of the frame 3 in the flow direction of the coolant (the width direction Y) . Accordingly, the dimension in the width direction Y of the power conversion apparatus 1 can be reduced easily.

Further, since the outer diameter of the distal end portion 201 can be made larger than that of the proximal end portion 200 without increasing the dimension in the width direction Y of the power conversion apparatus 1, the amount of coolant flowing inside the cooler 2 can be increased easily. Hence, the power conversion apparatus 1 can have excellent cooling performance.

The semiconductor modules 10 are arranged in a row along the stacking direction X such that each one of them is disposed between each adjacent two of the cooling tubes 21. Accordingly, the total amount of heat generated by the semiconductor modules 10 is small compared to a case where two or more of the semiconductor modules 120 are disposed between each adjacent two of the cooling tubes 21. Further, the temperature of the coolant flowing to cool the respective semiconductor modules 10 can be made uniform easily compared to the case where two or more of the semiconductor modules 120 are disposed between each adjacent two of the cooling tubes 21. By the respective or synergistic effects of those advantages, the power conversion apparatus 1 can efficiently cool the semiconductor modules 10.

Further, since the amount of heat generated between each adjacent two of the cooling tubes 21 is small, which facilitates cooling of the semiconductor modules 10, the outer diameter of the proximal end portion 200 can be made smaller. Further, since the semiconductor modules 10 are arranged in a single row and not in multiple rows, the dimension in the width direction Y of the power conversion apparatus 1 can be further reduced.

The frame 3 includes a plurality of the bosses 32 formed so as to be able to fasten the control circuit board 14 for controlling the operations of the semiconductor modules 10, at least one pair of the bosses 3 being disposed adjacently outside in the width direction Y of the proximal end portions 200 of the pair of the coolant inlet/outlet tubes 20. Accordingly, a dead space occurring outside in the width direction Y of the proximal end portions 200 of the pair of the coolant inlet/outlet tubes 20 can be used as a space for disposing the bosses 32. Further, disposing the bosses 32 in the way described above makes it possible to locate the fastening positions of the control circuit board 14 close to its four corners so that the control circuit board 14 can be fixed stably.

### Second Embodiment

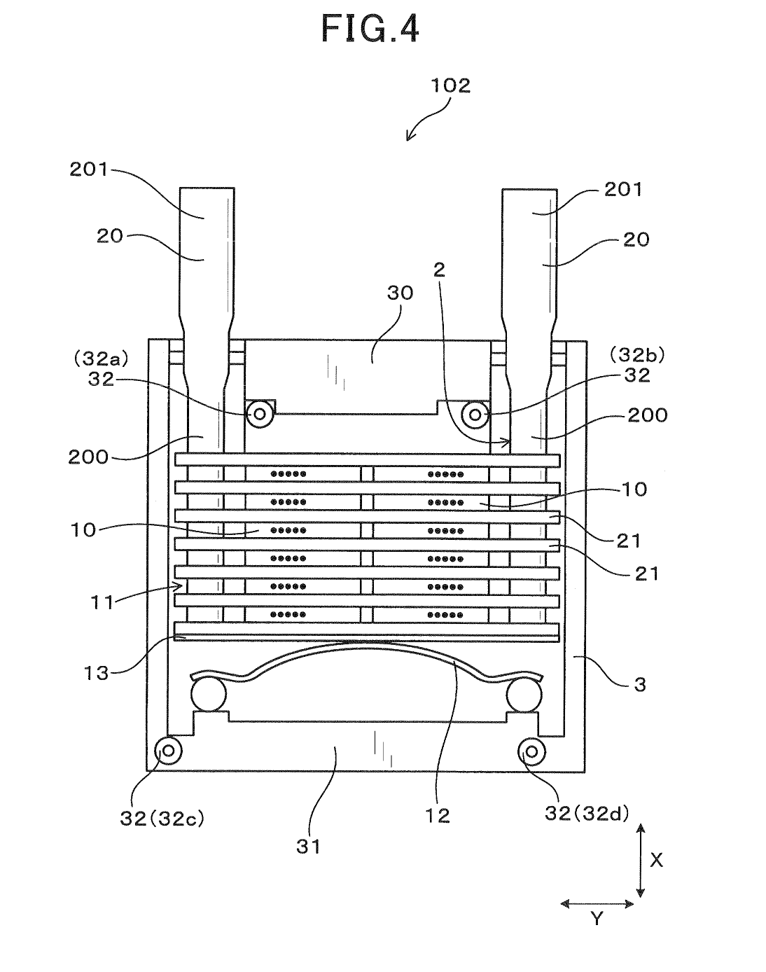

Next, a power conversion apparatus 102 according to a second embodiment of the invention is described. The difference between the first embodiment and the second embodiment is in the layout of the semiconductor modules 10. As shown in FIG. 4, in the power conversion apparatus 102 according to the second embodiment of the invention, each two of the semiconductor modules 10 are disposed side by side in the width direction Y between each adjacent two of the cooling tubes 21. That is, the semiconductor modules 10 are arranged in two rows extending in the stacking direction X.

In the second embodiment, of the four bosses 32 provided in the frame 3, the bosses 32a and 32b disposed on the side of the first wall portion 30 are located adjacently inside in the width direction Y of the proximal end portions 200 of the pair of the coolant inlet/outlet tubes 20.

According to also the second embodiment in which more than one semiconductor module 10 is disposed between each adjacent two of the cooling tubes 21, it is possible to reduce the dimension of the frame 3 in the flow direction of the coolant (the width direction Y) to thereby reduce the dimension in the width direction Y of the power conversion apparatus, if the outer diameter of the proximal end portion 200 is smaller than that of the distal end portion 201 in at least one of the pair of the coolant inlet/outlet tubes 20.

Further, since the outer diameter of the distal end portion 201 can be made larger than that of the proximal end portion 200 without increasing the dimension in the width direction Y of the power conversion apparatus 102, the amount of coolant flowing inside the cooler 2 can be increased easily to increase the cooling performance.

### Third Embodiment

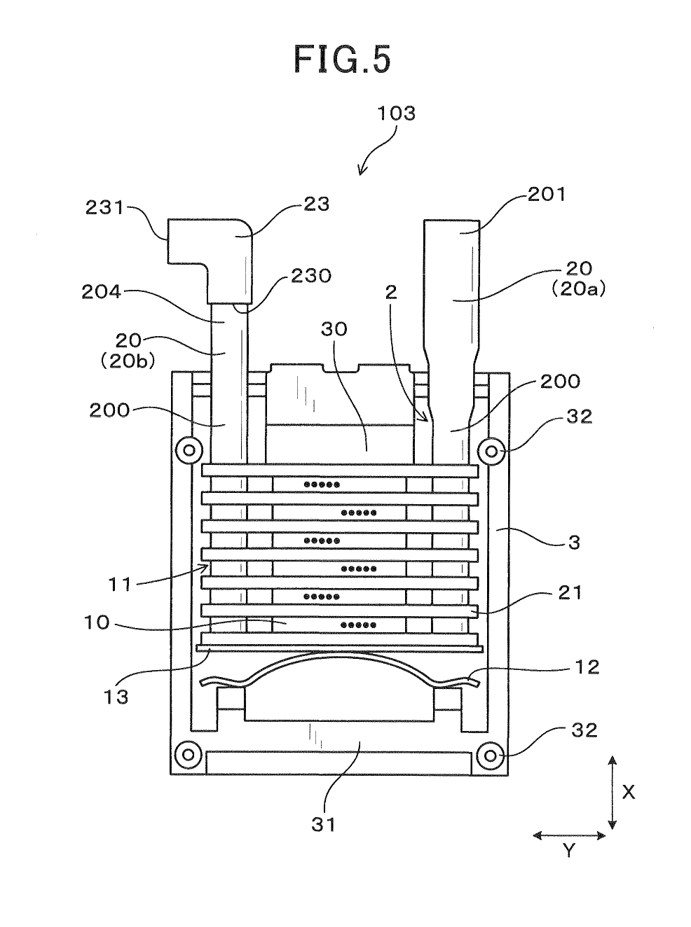

Next, a power conversion apparatus 103 according to a third embodiment of the invention is described. In the third embodiment, of the pair of the coolant inlet/outlet tubes 20a and 20b, only the coolant inlet/outlet tube 20a is formed with the distal end portion 201 whose outer diameter is larger than that of the proximal end portion 200. As shown in FIG. 5, the power conversion apparatus 103 according to the third embodiment of the invention has the structure in which the diameter of the distal end portion 201 of the coolant inlet/outlet tube 20a is larger than that of the proximal end portion 200 as is the case with the first embodiment, while the diameter of the distal end portion 204 of the coolant inlet/outlet tube 20b is the same as that of the proximal end portion 200.

As shown in FIG. 5, the power conversion apparatus 103 of this embodiment is used together with a connection adapter 23 mounted on the distal end portion 204 of the coolant inlet/outlet tube 20b for connection between the coolant inlet/outlet tube 20b and an external tube. The connection adapter 23 is a cylindrical pipe bent at approximately a right angle at its center. The distal end portion 204 of the coolant inlet/outlet tube 20b is inserted into one open end 230 of the connection adapter 23. The other open end 231 of the connection adapter 23, which is connected to the external tube, opens in the width direction Y.

The third embodiment provides the same advantages as those provided by the first embodiment, if only the coolant inlet/outlet tube 20a is formed with the distal end portion 201 whose outer diameter is larger than that of the proximal end portion 200. In the third embodiment, the coolant may be introduced into the cooler 2 from the coolant inlet/outlet tube 20a, or the other coolant inlet/outlet tube 20b. The open end 231 of the connection adapter 23 may open in the height direction Z.

In the first to third embodiments described above, the coolant passage is formed by the cooling tubes 21, and the cooling tubes 21 are in contact with the semiconductor modules 10. However, the coolant passage and the semiconductor modules 10 may be formed integrally with each other so that the coolant directly contacts the semiconductor modules 10.

In the above embodiments, the spring member 12 is disposed on the side of the second wall portion 31 of the frame 3. However, it maybe disposed on the side of the pair of the coolant inlet/outlet tubes 20. That is, the spring member 12 may be disposed between the pair of the coolant inlet/outlet tubes 20 so that the stacked body 11 is pressed toward the second wall portion 31.

The above explained preferred embodiments are exemplary of the invention of the present application which is described solely by the claims appended below. It should be understood that modifications of the preferred embodiments may be made as would occur to one of skill in the art.

What is claimed is:

1. A power conversion apparatus comprising:
semiconductor modules constituting a part of a power conversion circuit;
a cooler including coolant passages; and
a frame holding the semiconductor modules and the cooler;
wherein
the semiconductor modules and the coolant passages are stacked on one another so as to form a stacked body,
the cooler includes a pair of inlet/outlet tubes for introducing and discharging a coolant, the pair of the coolant inlet/outlet tubes extending from one of the coolant passages which is located at one end in a stacking direction of the stacked body to outside of the frame,
each of the pair of the coolant inlet/outlet tubes includes a proximal end portion located inside the frame and a distal end portion located outside the frame, and
in at least one of the pair of the inlet/outlet tubes, the proximal end portion has an outer diameter smaller than an outer diameter of the distal end portion.

2. The power conversion apparatus according to claim 1, wherein the semiconductor modules are disposed in a row such that each one of the semiconductor modules is disposed between each adjacent two of the cooling passages.

3. The power conversion apparatus according to claim 1, wherein
the frame includes bosses projecting in a direction perpendicular to both the stacking direction of the stacked body and a flow direction of the coolant passages as a width direction of the power conversion apparatus,
the bosses are shaped to be able to fasten thereon a control circuit board for controlling operations of the semiconductor modules, and
at least paired two of the bosses being located adjacently outside in the width direction of the distal end portions of the pair of the coolant inlet/outlet tubes.
